(19) United States
(12) Patent Application Publication
(10) Pub. No.: US 2008/0158978 A1
(43) Pub. Date: Jul. 3, 2008

(54) MEMORY READ CIRCUIT AND MEMORY APPARATUS USING THE SAME

(75) Inventor: Hideki NISHIYAMA, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Kyoto (JP)

(21) Appl. No.: 11/962,216

(22) Filed: Dec. 21, 2007

(30) Foreign Application Priority Data
Dec. 27, 2006 (JP) 2006-353138

(51) Int. Cl. G11C 16/06; G11C 7/00

(52) U.S. Cl. 365/185.18; 365/189.15; 365/189.12

(57) ABSTRACT

A memory read circuit includes k sense amplifiers provided for respective k bit lines and reading out data from their corresponding bit lines, where k is a natural number, a shift register that includes k flip-flops connected in cascade and arranged to hold outputs from corresponding sense amplifiers, and to output the outputs from the k sense amplifiers as serial data, and expected value setting section arranged to store in the k flip-flops expected value data on the outputs from the corresponding sense amplifiers, and a determination section arranged to determine whether the expected value data stored in the flip-flops matches the outputs from the corresponding sense amplifiers.

### BACKGROUND OF THE INVENTION

1. Field of the Invention

The present invention relates to a memory and more particularly to a testing technique of the memory.

2. Description of the Related Art

In a recent semiconductor integrated circuit, a memory apparatus including memory cells arranged in a matrix is used in order to store data. Such a memory apparatus includes sense amplifiers provided for respective bit lines (data lines) which are provided for respective columns of the matrix. Data in a memory cell is read out by a corresponding sense amplifier, the data is held in a flip-flop or the like, and the data is outputted to an external circuit.

A memory apparatus may latch outputs from sense amplifiers in a word unit, convert the outputs into serial data by a shift register, and then output the serial data. See for example, Japanese Patent Application Laid-Open No. 2002-93162.

A memory apparatus is subjected to an inspection prior to shipment as to whether the memory apparatus can properly write data into memory cells and read out the data. Here, an inspection time for the case in which data read out by sense amplifiers is to be converted into serial data will be considered.

First, predetermined data is written into memory cells which are inspection targets. When one word is 8 bits, first, data for one word is read out from the memory cells and the data is written in parallel into eight flip-flops. Subsequently, a clock signal is provided to a shift register and the 8-bit data is sequentially outputted. The output from the shift register is compared with the predetermined data written into the respective memory cells to determine whether they match. In this technique, at least such a number of clocks that corresponds to the number of bits (8 in this example) for one word is required for the inspection of memory cells.

When this step is performed on all columns, the number of clocks (=the number of bits per word×the number of words) is required. A reduction in inspection time is an important issue in order to increase throughput in a semiconductor manufacturing process.

### SUMMARY OF THE INVENTION

In order to overcome the problems described above, preferred embodiments of the present invention reduce an inspection time for a memory and provide a memory read circuit that reads out k-bit (k is a natural number) data from bit lines provided for respective columns of memory cells arranged in a matrix and outputs the data as serial data.

The memory read circuit preferably includes k sense amplifiers provided for the respective k bit lines and reading out data from their corresponding bit lines; a shift register that has k flip-flops connected in cascade and holding outputs from their corresponding sense amplifiers, and outputs the outputs from the k sense amplifiers as serial data; an expected value setting section that stores in the k flip-flops expected value data on the outputs from the corresponding sense amplifiers; and a determination section that determines whether the expected value data stored in the flip-flops matches the outputs from the corresponding sense amplifiers.

Test data is written into memory cells which are inspection targets and the shift register is used as a memory for storing expected value data (correct values) for the test data. Then, the test data is read out by corresponding sense amplifiers from the memory cells, and the test data is compared with outputs from the sense amplifiers. As a result, correct values are written into the memory cells and whether read-out is properly performed can be determined.

According to this aspect, upon inspecting memory cells, test data for one word is read out to the shift register and thus there is no need to output data on a bit-by-bit basis. As a result, the number of clocks required for inspection can be reduced, making it possible to reduce an inspection time.

The determination section may include a plurality of first logic gates which are provided for respective pairs of the flip-flops and the sense amplifiers, and to each of which two data units are inputted; and a second logic gate which is provided for each shift register and to which outputs from the plurality of first logic gates provided for the respective flip-flops in the shift register are inputted.

According to this aspect, the occurrence of error in each memory cell can be detected from the outputs from the first logic gates, and whether an error occurs in one word can be detected from an output from the second logic gate.

The expected value setting section may sequentially input expected value data to a D terminal of a shift register in a first stage.

The memory read circuit may be integrally packaged on a semiconductor substrate. The expression “integrally packaged” includes the case in which all components of the circuit are formed on a semiconductor substrate and the case in which the main components of the circuit are integrally packaged. Some resistors, capacitors, or the like, may be provided outside the semiconductor substrate, for circuit constant adjustment. By packaging the circuit as a single IC, its area can be reduced.

Another preferred embodiment of the present invention provides a memory apparatus including a memory array having memory cells arranged in a matrix of m rows and n columns (m and n are natural numbers); and a plurality of the above-described memory read circuits which are arranged in parallel with each other.

According to this aspect, an inspection time for a memory can be reduced.

The memory array may be an EEPROM (Electrically Erasable and Programmable Read Only Memory).

Note that arbitrary combinations of the aforementioned components and expressions of the present invention which are converted between methods, apparatuses, and the like, are also effective as preferred embodiments of the present invention.

According to various preferred embodiments of the present invention, an inspection time for a memory can be reduced.

Other features, elements, steps, characteristics and advantage of the present invention will become more apparent from the following detailed description of preferred embodiments of the present invention with reference to the attached drawings.

### BRIEF DESCRIPTION OF THE DRAWINGS

FIG. 1 is a circuit diagram showing a configuration of a read circuit according to a preferred embodiment of the present invention.

FIG. 2 is a block diagram showing the overall configuration of a memory apparatus including the read circuit in FIG. 1.

### DETAILED DESCRIPTION OF THE PREFERRED EMBODIMENTS

Various preferred embodiments of the present invention will be described in the following paragraphs with reference to the drawings.

The present invention will be described below based on preferred embodiments with reference to the drawings. Note that the same or corresponding components, members, and processes in the drawings are denoted by the same reference symbols and overlapping description thereof is appropriately omitted. Note also that the preferred embodiments are merely exemplary and are in no way intended to limit the invention, and all features described in the preferred embodiments and combinations of such features are not necessarily the nature of the invention.

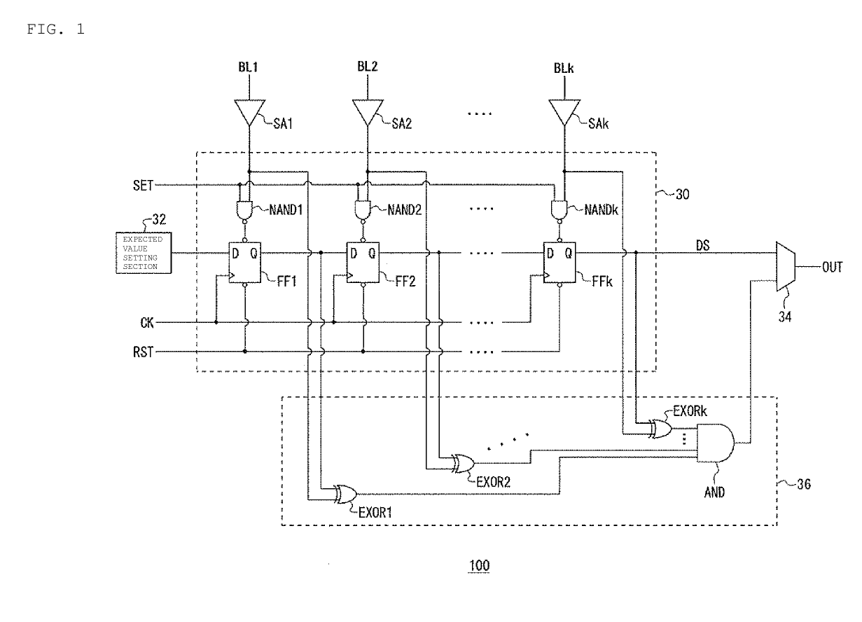

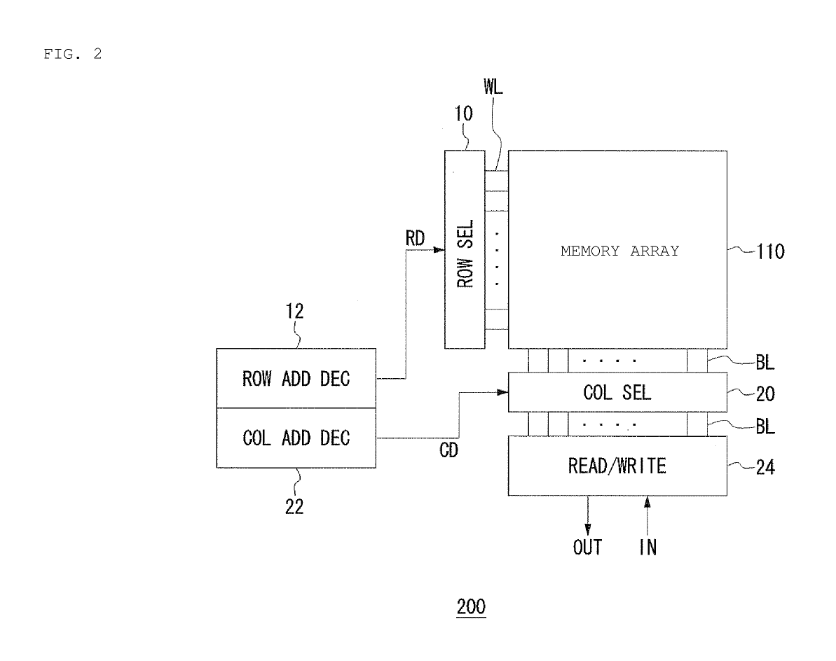

FIG. 1 is a circuit diagram showing a configuration of a read circuit 100 according to a preferred embodiment of the present invention. FIG. 2 is a block diagram showing the overall configuration of a memory apparatus 200 including the read circuit 100 in FIG. 1.

The memory apparatus 200 in FIG. 2 is an EEPROM (Electrically Erasable and Programmable Read Only Memory), for example, and includes a memory array 110, a row selection circuit 10, a row decoder 12, a column selection circuit 20, a column decoder 22, and a read/write circuit 24. It is preferable that the memory apparatus 200 be integrally packaged on a semiconductor substrate.

The memory array 110 includes memory cells arranged in a matrix of m rows and n columns (m and n are natural numbers). The memory array 110 includes word lines WL1 to WLm provided for respective rows of the matrix; and bit lines BL1 to BLn provided for the respective columns.

The row selection circuit 10 includes m word line drivers (not shown) provided for the respective m word lines. The row decoder 12 receives address data on an access target, decodes the address data, and thereby generates row address data RD, and then outputs the row address data RD to the row selection circuit 10. As a result, in the row selection circuit 10, a word line driver specified by the row address data RD is selected and a required voltage is outputted to a selected word line WL.

The column selection circuit 20 includes n selector circuits (not shown) that select the bit lines BL provided for the respective columns of the memory array 110. The column decoder 22 receives address data on an access target, decodes the address data, and thereby generates column address data CD, and then outputs the column address data CD to the column selection circuit 20. As a result, in the column selection circuit 20, a selector circuit specified by the column address data CD is selected and a required bit line voltage is outputted to a selected bit line BL.

In the read/write circuit 24, switching between a write mode and a read mode is performed. In a write mode, input data IN to be written into the memory array 110 is inputted to the read/write circuit 24 and the input data IN is written into a memory cell located at an intersection of a word line WL and a bit line BL which are respectively selected by the row selection circuit 10 and the column selection circuit 20.

In a read mode, the read/write circuit 24 reads out data from a memory cell located at an intersection of a word line WL and a bit line BL which are respectively selected by the row selection circuit 10 and the column selection circuit 20, and outputs the data as output data OUT. The output data OUT is outputted as serial data in a word unit.

Referring back to FIG. 1, the read circuit 100 in FIG. 1 is a circuit that reads out data from memory cells, and FIG. 1 shows a circuit configuration for one word which is the unit of memory access in the read/write circuit 24 in FIG. 2. That is, the read/write circuit 24 is configured by a plurality of read circuits 100 in FIG. 1. In the following description, it is assumed that one word is 8 bits.

The read circuit 100 in FIG. 1 reads out data of k bits (k is a natural number) from bits lines BL1 to BLk provided for respective columns of memory cells arranged in a matrix, and outputs the data as serial data DS. The k may correspond to the number of bits for one word which is the unit of memory access. For example, k=8, 16, or the like, and it is designed according to the bus width.

The read circuit 100 includes sense amplifiers SA1 to SAk, a shift register 30, an expected value setting section 32, a selector 34, and a determination section 36. The sense amplifiers SA1 to SAk are provided for the respective k bit lines BL1 to BLk and read out data from their corresponding bit lines.

The shift register 30 includes flip-flops FF1 to FFk and NAND gates NAND1 to NANDk. The flip-flops FF1 to FFk hold outputs from their corresponding sense amplifiers SA1 to SAk. The shift register 30 is configured such that outputs from the k sense amplifiers SA1 to SAk can be parallel loaded. The shift register 30 converts loaded k-bit data into serial data DS and then outputs the serial data DS.

The flip-flops FF1 to FFk in FIG. 1 preferably are, for example, D flip-flops connected in cascade and an output terminal of a flip-flop FFi in an i-th stage is connected to a D terminal (input terminal) of a flip-flop FFi+1 in an i+1-th stage.

A clock signal CK is inputted to respective clock terminals of the flip-flops FF1 to FFk and a reset signal RST is inputted to respective reset terminals (inverse logic). Outputs from the sense amplifiers SA1 to SAk are respectively set (stored) in the flip-flops FF1 to FFk by the corresponding NAND gates NAND1 to NANDk. An output from a sense amplifier SAi and a set signal SET are inputted to an i-th NAND gate NANDi, and a NAND is outputted. An output signal from the NAND gate NANDi is inputted to a set terminal (inverse logic) of the flip-flop FFi.

Reading out (loading) of data by the shift register 30 will be described. First, prior to reading out data, a reset signal RST is set from a high level to a low level. As a result, all of the flip-flops FF1 to FFk are reset and 0 is written as data.

Subsequently, the data in the memory cells are amplified and read out by the sense amplifiers SA1 to SAk and a set signal SET is set to a high level. At this time, if an output from a sense amplifier SAi is 1, then an output from a NAND gate NAND1 is a low level and thus a flip-flop FFi is set and 1 is stored. If an output from the sense amplifier SAi is 0, then an output from the NAND gate NAND1 is a high level and thus the flip-flop FFi is not set and the data remains 0.

Subsequently, by inputting a clock signal CK, the data stored in the flip-flops FF1 to FFk is transmitted to flip-flops in their subsequent stages and then sequentially outputted as serial data DS from an output terminal of a k-th flip-flop FFk in the last stage.

The expected value setting section 32, the determination section 36, and the selector 34 are provided for inspection of the memory apparatus 200.

Upon inspection of the memory apparatus 200, the expected value setting section 32 stores in the k flip-flops FF1 to FFk expected value data on outputs from their corresponding sense amplifiers SA1 to SAk. For example, when test data read out from the sense amplifier SA1 is 1, its expected value data is 1. The expected value data on an output refers to a logical value for test data to be written into a memory cell upon inspection of the memory apparatus 200. Therefore, expected value data is test data itself.

In the present preferred embodiment, upon inspection, a clock signal CK is provided to the flip-flops FF1 to FFk. In synchronization with the clock signal CK, the expected value setting section 32 sequentially inputs expected value data to a D terminal of the flip-flop FF1 in the first stage in the shift register 30. As a result, the expected value data is stored in the flip-flops FF1 to FFk. In this case, the storing of expected value data requires k clocks.

The determination section 36 determines whether expected value data stored in the respective flip-flops FF1 to FFk matches outputs from their corresponding sense amplifiers SA1 to SAk.

The determination section 36 includes exclusive-OR gates EXOR1 to EXORk which are first logic gates; and an AND gate AND which is a second logic gate. The exclusive-OR gates EXOR1 to EXORk are provided for respective pairs of the flip-flops FF1 to FFk and the sense amplifiers SA1 to SAk. Output data from a sense amplifier and output data from a flip-flop are inputted to a corresponding exclusive-OR gate. The exclusive-OR gate EXOR outputs 1 (high level) when two data units match, and outputs 0 (low level) when two data units do not match. When error does not occur in a data write/read step, two data units are supposed to match. Thus, the output from an exclusive-OR gate EXOR being 1 indicates that error has occurred in a corresponding bit.

Outputs from the k exclusive-OR gates EXOR1 to EXORk are inputted to the AND gate AND. An output from the AND gate AND is 1 when error occurs in any of the bits.

An output from the AND gate AND is inputted to the selector 34, together with serial data DS. The selector 34 selects the serial data DS upon normal operation and selects output data from the determination section 36 upon testing.

The operation of the read circuit 100 configured in the above-described manner, which is performed upon testing, will be described. When the read circuit 100 is set to a test mode, the selector 34 selects an output from the determination section 36. First, the read circuit 100 writes test data into arbitrary memory cells on the bit lines BL1 to BLk. It is desirable that the same test data be written into memory cells on the same bit line. Along with this, the expected value setting section 32 stores test data in the flip-flops FF1 to FFk as expected value data.

Subsequently, the sense amplifiers SA1 to SAk read out the data written into the memory cells. At this time, the exclusive-OR gates EXOR1 to EXORk determine whether the expected value data matches the output data read out by the sense amplifiers SA. When error occurs in any of the bits, output data from the selector 34 is 1 and when there is no error in all bits, the output data is 0.

Here, the time required for testing is considered. According to the read circuit 100 according to the present preferred embodiment, a determination as to whether test data for k bits has a correct value can be made simultaneously and in parallel.

On the other hand, conventional inspection techniques require the following process. Specifically, outputs from the sense amplifiers SA1 to SAk are temporarily read out to the flip-flops FF1 to FFk. Subsequently, data in the flip-flops FF1 to FFk is converted into serial data by the shift register. Then, each bit of the serial data which is sequentially outputted is compared with expected value data. That is, in the conventional techniques, at least k clocks are required for serial/parallel conversion, and as a result, an inspection time becomes long.

Hence, according to the read circuit 100 according to the present preferred embodiment, the time required for inspection can be reduced over the conventional techniques. Note that, in the present preferred embodiment, the expected value setting section 32 stores in the k flip-flops FF1 to FFk expected value data on outputs from their corresponding sense amplifiers SA1 to SAk. In the present preferred embodiment, the same test data is stored in memory cells on the same bit line BL. Therefore, storing of expected value data for m word lines can be done by a single storage operation. Accordingly, the larger the number of word lines, the more remarkable the effect of reducing an inspection time by the read circuit 100 according to the present preferred embodiment.

It is to be understood by those skilled in the art that the above-described preferred embodiment is merely exemplary and thus various variants are possible for combinations of components or processing processes in the preferred embodiment and such variants are also encompassed within the scope of the present invention. Variants will be exemplified below.

Although, in a preferred embodiment, a circuit using D flip-fops as the shift register 30 is exemplified, the present invention is not limited thereto and various known shift registers or shift registers of configurations which are expected to be considered in the future can be used. Writing of data into a shift register may be performed through terminals other than set terminals, e.g., D terminals.

Although, in a preferred embodiment, expected value data is supplied to the D terminal of the flip-flop FF1 by the expected value setting section 32 and by shifting the data the expected value data is stored in the flip-flops FF1 to FFk, the present invention is not limited thereto. For example, storing of expected value data may be performed through set terminals of respective D flip-flops.

The configurations of logical circuits such as the shift register 30 and the determination section 36 are not limited to those shown in FIG. 1 and various variants are also encompassed within the scope of the present invention.

While preferred embodiments and examples of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A memory read circuit, comprising:
k sense amplifiers provided for respective k bit lines and reading out data from their corresponding bit lines, where k is a natural number;
a shift register that includes k flip-flops connected in cascade and arranged to hold outputs from corresponding sense amplifiers, and to output the outputs from the k sense amplifiers as serial data;
an expected value setting section arranged to store in the k flip-flops expected value data on the outputs from the corresponding sense amplifiers; and
a determination section arranged to determine whether the expected value data stored in the flip-flops matches the outputs from the corresponding sense amplifiers.

2. The memory read circuit according to claim 1, wherein the determination section includes k first logic gates which are provided for respective pairs of the flip-flops and the sense amplifiers, and to each of which two data units are inputted, and a second logic gate, to which outputs from the k first logic gates are inputted.

3. The memory read circuit according to claim 1, wherein the expected value setting section is arranged to sequentially input expected value data to a D terminal of a flip-flop in a first stage.

4. The memory read circuit according to claim 1, wherein the memory read circuit is integrally packaged on a semiconductor substrate.

5. The memory read circuit according to claim 2, wherein the memory read circuit is integrally packaged on a semiconductor substrate.

6. The memory read circuit according to claim 3, wherein the memory read circuit is integrally packaged on a semiconductor substrate.

7. A memory apparatus comprising:
a memory array including memory cells arranged in a matrix of m rows and n columns, where m and n are natural numbers; and
a plurality of memory read circuits according to claim 1 which are arranged in parallel with each other.

8. A memory apparatus comprising:
a memory array including memory cells arranged in a matrix of m rows and n columns, where m and n are natural numbers; and
a plurality of memory read circuits according to claim 2 which are arranged in parallel with each other.

9. A memory apparatus comprising:
a memory array including memory cells arranged in a matrix of m rows and n columns, where m and n are natural numbers; and
a plurality of memory read circuits according to claim 3 which are arranged in parallel with each other.

10. The memory apparatus according to claim 7, wherein the memory array is an Electrically Erasable and Programmable Read Only Memory.

11. The memory apparatus according to claim 8, wherein the memory array is an Electrically Erasable and Programmable Read Only Memory.

12. The memory apparatus according to claim 9, wherein the memory array is an Electrically Erasable and Programmable Read Only Memory.

13. A memory read circuit comprising:
k sense amplifiers provided for respective k bit lines and reading out data from corresponding bit lines, where k is a natural number;
a shift register that includes k flip-flops connected in cascade and arranged to hold outputs from their corresponding sense amplifiers, and to output the outputs from the k sense amplifiers as serial data;
an expected value setting section arranged to store in the k flip-flops expected value data on the outputs from the corresponding sense amplifiers; and
a determination section arranged to compare the expected value data stored in the flip-flops with the outputs from the corresponding sense amplifiers and determine the compared data as a mismatch when there is even one mismatch data unit.

14. The memory read circuit according to claim 13, wherein the determination section includes k first logic gates which are provided for respective pairs of the flip-flops and the sense amplifiers, and to each of which two data units are inputted, and a second logic gate, to which outputs from the k first logic gates are inputted.

15. The memory read circuit according to claim 13, wherein the expected value setting section is arranged to sequentially input expected value data to a D terminal of a flip-flop in a first stage.

16. The memory read circuit according to claim 13, wherein the memory read circuit is integrally packaged on a semiconductor substrate.
